(19) United States
(12) Patent Application Publication
(10) Pub. No.: US 2022/0140062 A1
(43) Pub. Date: May 5, 2022

(54) DISPLAY DEVICE AND METHOD OF MANUFACTURING THE SAME

(71) Applicant: SAMSUNG DISPLAY CO., LTD., YONGIN-SI (KR)

(72) Inventor: DUCKJUNG LEE, HWASEONG-SI (KR)

(21) Appl. No.: 17/465,468

(22) Filed: Sep. 2, 2021

(30) Foreign Application Priority Data
Nov. 2, 2020 (KR) 10-2020-0144153

(51) Int. Cl. H01L 27/32; H01L 51/00; H01L 51/56

(52) U.S. Cl. CPC H01L 27/3293; H01L 2227/326; H01L 51/56; H01L 51/003

(57) ABSTRACT

A method of manufacturing a display device includes forming a sacrificial layer on a carrier substrate, forming a first base layer on the carrier substrate that surrounds the sacrificial layer and includes a different material from the sacrificial layer, forming pad electrodes on the first base layer that contact the sacrificial layer, forming a pixel structure on the first base layer that is electrically connected to the pad electrodes, separating the carrier substrate from the first base layer and the sacrificial layer, removing the sacrificial layer to expose the pad electrodes, and attaching a conductive film under the pad electrodes that contacts the pad electrodes.

### CROSS-REFERENCE TO RELATED APPLICATION(S)

This application claims priority under 35 USC § 119 from Korean Patent Application No. 10-2020-0144153, filed on Nov. 2, 2020 in the Korean Intellectual Property Office, the contents of which are herein incorporated by reference in their entirety.

### 1. Technical Field

Embodiments of the present inventive concept ate directed to a display device. More particularly, embodiments of the present inventive concept are directed to a tiled display device that has a rear bonding structure and method of manufacturing the same.

### 2. Discussion of the Related Art

A display device includes a display area in which an image is displayed and a peripheral area in which an image is not displayed. Recently, a tiled display device has been manufactured that combines a plurality of sub-display panels to implement a large screen. However, when the sub-display panels have the peripheral area at the edge and are combined with each other, a seam-line may be visually recognized by a user. For this reason, a display quality of the tiled display device may decrease.

To reduce a size of the peripheral area, a rear bonding structure is being studied and developed.

### SUMMARY

Embodiments of the present inventive concept provide a display device with improved reliability and improved display quality.

Embodiments of the present inventive concept also provide a method of manufacturing a display device with improved reliability and improved display quality.

A method of manufacturing a display device according to an embodiment includes forming a sacrificial layer on a carrier substrate, forming a first base layer on the carrier substrate where the first base layer surrounds the sacrificial layer and includes a different material from the sacrificial layer, forming pad electrodes on the first base layer where the pad electrodes contact the sacrificial layer, forming a pixel structure on the first base layer where the pixel structure is electrically connected to the pad electrodes, separating the carrier substrate from the first base layer and the sacrificial layer, removing the sacrificial layer where an opening is formed in the first base layer that exposes the pad electrodes, and attaching a conductive film in the opening of the first base layer where the conductive film contacts the pad electrodes.

In an embodiment, the first base layer contacts a side surface of the sacrificial layer and exposes an upper surface of the sacrificial layer.

In an embodiment, an upper surface of the sacrificial layer is substantially coplanar with an upper surface of the first base layer.

In an embodiment, a thickness of the first base layer is substantially the same as a thickness of the sacrificial layer.

In an embodiment, a thickness of the first base layer is less than a thickness of the sacrificial layer.

In an embodiment, the method further includes forming a protective layer on the first base layer after forming the first base layer. The protective layer surrounds the sacrificial layer and includes a material that differs from that of the sacrificial layer and the first base layer.

In an embodiment, the protective layer contacts a side surface of the sacrificial layer and exposes an upper surface of the sacrificial layer.

In an embodiment, an upper surface of the sacrificial layer may define a substantially same plane surface as an upper surface of the protective layer.

In an embodiment, the method further includes forming a second base layer on the first base layer after forming the pad electrodes. The second base layer includes substantially a same material as that of the first base layer and covers the pad electrodes.

In an embodiment, the sacrificial layer includes a fluorine-based polymer.

In an embodiment, the sacrificial layer is formed by a photolithography process or an inkjet printing process.

In an embodiment, the sacrificial layer is removed using a fluorine-based solvent.

In an embodiment, the sacrificial layer extends in a first direction. The pad electrodes are spaced apart from each other in the first direction. Each of the pad electrodes extends in a second direction perpendicular to the first direction.

A display device according to an embodiment includes a first base layer that includes a first material and a first opening, pad electrodes disposed on the first base layer where the pad electrodes are exposed by the first openings, a pixel structure disposed on the first base layer where the pixel structure is electrically connected to the pad electrodes, and a conductive film disposed in the first opening where the conductive film contacts the pad electrodes. A second material that differs from the first material is adsorbed on at least a portion of an inner side surface of the first opening of the first base layer.

In an embodiment, the second material includes a fluorine-based polymer.

In an embodiment, the inner side surface of the first base layer is smooth.

In an embodiment, the display device further includes a protective layer disposed between the first base layer and the pad electrodes, wherein the protective layer includes a third material that differs from the first and second materials and a second opening that overlaps the first opening. The second material is adsorbed on at least a portion of an inner side surface of the second opening of the protective layer.

In an embodiment, the inner side surface of the first base layer is substantially coplanar with the inner side surface of the protective layer.

In an embodiment, the display device further includes a second base layer disposed on the first base layer, wherein the second base layer includes the first material and covers the pad electrodes.

In an embodiment, the first opening may extend in a first direction. The pad electrodes may be spaced apart from each other in the first direction. Each of the pad electrodes may extend in a second direction perpendicular to the first direction.

A display device according to an embodiment includes a base layer that includes a first material and a first opening; pad electrodes disposed on a first surface of the base layer where the pad electrodes are exposed by the first opening; an integrated circuit disposed on a second surface of the base layer where the second surface is opposite to the first surface of the base layer; and a conductive film disposed in the first opening where the conductive film electrically connects the pad electrodes to the integrated circuit. The first opening extends in a first direction. The pad electrodes are spaced apart from each other in the first direction, and each of the pad electrodes extends in a second direction perpendicular to the first direction.

In an embodiment the display device further includes transmission lines on the first surface of the base layer where the transmission lines electrically connect the pad electrodes to a signal transmission line.

In an embodiment, the display device further includes a pixel structure disposed on the base layer where the pixel structure is electrically connected to the pad electrodes. The pixel structure includes a light-emitting element and a driving element that drives the light-emitting element, and the driving element includes at least one thin film transistor.

In an embodiment, the integrated circuit is a data driver, and the signal transmission line connects the pad electrodes to a data line that transmits data signals received from the data driver through the pad electrodes to a source electrode of the at least one thin film transistor.

In an embodiment, the integrated circuit is a gate driver, and the signal transmission line connects the pad electrodes to a gate line that transmits gate signals received from the gate driver through the pad electrodes to a gate electrode of the at least one thin film transistor.

In an embodiment, a second material that differs from the first material is adsorbed on at least a portion of an inner side surface of the first opening of the base layer.

### BRIEF DESCRIPTION OF THE DRAWINGS

FIG. 1 is a block diagram of a display device according to an embodiment.

FIG. 2 is a rear view of an area “A” of FIG. 1.

FIG. 3 is a cross-sectional view taken along line I-I′ of FIG. 2.

FIG. 4 is a cross-sectional view taken along line II-II′ of FIG. 2.

FIG. 5 is a cross-sectional view taken along line III-III′ of FIG. 2.

FIGS. 6 to 13 are cross-sectional views that illustrate a method of manufacturing a display device according to an embodiment.

FIG. 14 is a cross-sectional view of a display device according to an embodiment.

FIGS. 15 to 23 are cross-sectional views that illustrate a method of manufacturing a display device according to an embodiment.

### DETAILED DESCRIPTION

Illustrative, non-limiting embodiments will be more clearly understood from the following detailed description in conjunction with the accompanying drawings.

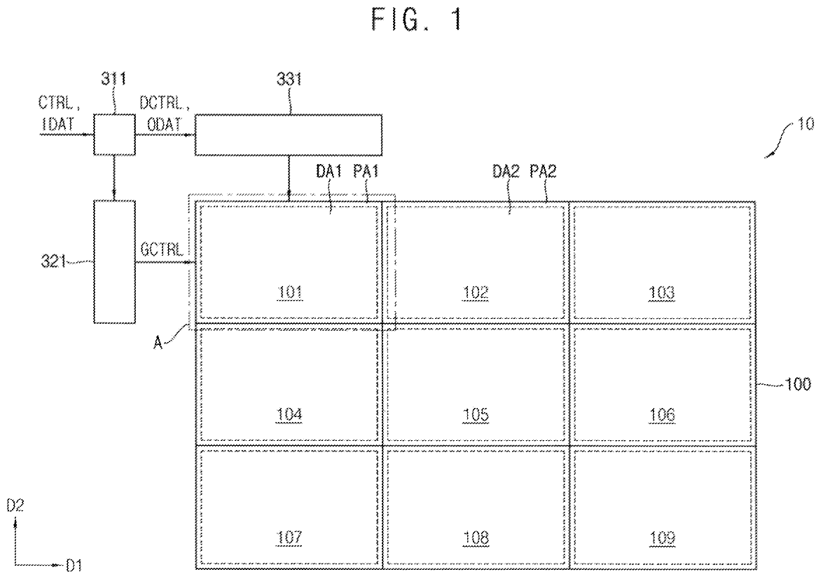

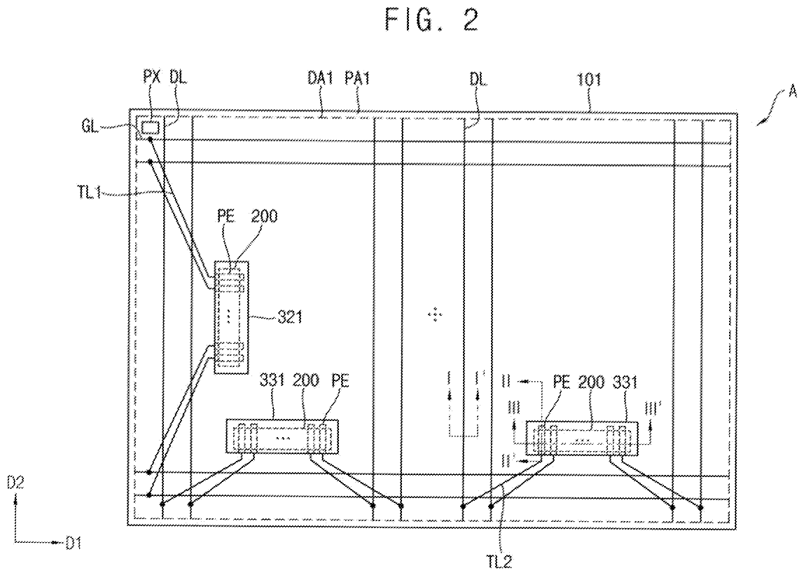

FIG. 1 is a block diagram illustrating a display device according to an embodiment. FIG. 2 is a rear view illustrating an area “A” of FIG. 1.

Referring to FIGS. 1 and 2, a display device 10 according to an embodiment includes a display panel 100 and a panel driver.

In an embodiment, the display panel 100 includes a plurality of sub-display panels. For example, as illustrated in FIG. 1, the display panel 100 includes first to ninth sub-display panels 101, 102, 103, 104, 105, 106, 107, 108 and 109 arranged in a 3'3 matrix form in a plan view. The first to ninth sub-display panels 101 to 109 display corresponding first to ninth images, respectively. A user can view an image in which the first to ninth images are combined. However, embodiments are not limited thereto, and may have various combinations. For example, in other embodiments, the sub-display panels may be arranged in various matrix forms, such as a 1×2, a 1×3, a 1×4, a 2×1, a 3×1, a 4×1, a 2×3, a 4×4, etc.

In an embodiment, each of the first to ninth sub-display panels 101, 102, 103, 104, 105, 106, 107, 108, and 109 includes a display area and peripheral area adjacent to the display area. In an embodiment, the first stab-display panel 101 include a first display area DA1 in which the first image is displayed and a first peripheral area PA1 adjacent to the first display area DA1. The second sub-display panel 102 includes a second display area DA2 in which the second image is displayed and a second peripheral area PA2 adjacent to the second display area DA2. For example, the first peripheral area PA1 surrounds the first display area DA1 and the second peripheral area PA2 surrounds the second display area DA2 in a plan view. It is desirable to minimize a distance between adjacent display areas so that a boundary between adjacent sub-display panels is not visually recognizable. For example, a distance between the first display area DA and the second display area DA2, such as sum of a width of the first peripheral area PA1 and a width of the second peripheral area PA2, is less than or equal to a pitch between adjacent pixels.

In an embodiment, the first sub-display panel 101 includes pixels PX, gate lutes GL, and data lines DL. The pixels PX are disposed in the first display area DA1 and are electrically connected to the gate lines GL and the data lines DL. A pixel structure is disposed in each of the pixels PX that includes a light-emitting element and a driving element that drives the light-emitting element. For example, the light-emitting element may include an organic light-emitting diode. For another example, the light-emitting element may include a nano light-emitting diode. The driving element may include at least one thin film transistor.

In an embodiment, the gate lines GL and the data lines DL cross each other. For example, each of the gate lines GL extends in first direction D1. The gate lines GL are arranged in a second direction D2 that crosses the first direction D1. Each of the data lines DL extends in the second direction D2. The data lines DL are arranged in the first direction D1. For example, the first direction D1 and the second direction D2 are perpendicular to each other.

In an embodiment, the panel driver includes a plurality of sub-panel drivers which drive corresponding panels of the plurality of sub-display panels, respectively. For example, a first sub-panel driver that drives the first sub-display panel 101 includes a first driving controller 311, a first gate driver 321, and a first data driver 331. Similarly, the second to ninth sub-display panels 102 to 109 are respectively driven by corresponding second to ninth sub-panel drivers.

In an embodiment, the first driving controller 311 generates a gate control signal GCTRL, a data control signal DCTIRL, and output image data ODAT based on an input image data IDAT and an input control signal CTRL received from an external device. For example, the input image data MAT may be RGB data that includes red image data, green image data, and blue image data. The input control signal CTRL includes a master clock signal and art input data enable signal. The input control signal CTRL may further include a vertical synchronization signal and a horizontal synchronization signal.

In an embodiment, the first gate driver 321 generates gate signals based on the gate control signal GCTRL received from the first driving controller 311. For example, the gate control signal GCTRL includes a vertical start signal and a gate clock signal. The first gate driver 321 sequentially outputs the gate signals to the gate lines GL in the first sub-display panel 101.

In an embodiment, the first data driver 331 generates data signals based on the data control signal DCTRL and the output image data ODAT received from the first driving controller 311. For example, the data control signal DCTRL includes an output data enable signal, a horizontal start signal, and a load signal. The first data driver 331 outputs the data signals to the data lines DL in the first sub-display panel 101.

In an embodiment, each of the first gate driver 321 and the first data driver 331 is implemented as an integrated circuit (IC). For example, as illustrated in FIG. 2, the first gate driver 321 and the first data driver 331 are disposed on a lower surface (a rear surface) of the first sub-display panel 101. Each of the first gate driver 321 and the first data driver 331 may be an IC chip, a substrate with an IC chip mounted thereon, a film with an IC chip mounted thereon, etc.

In an embodiment, the first gate driver 321 or the first data driver 331 is configured as two or more drivers and disposed on the lower surface of the first sub-display panel 101. For example, as illustrated in FIG. 2, the first gate driver 321 is configured as one driver, and the first data driver 331 is configured as two drivers. However, embodiments are not limited thereto, and in other embodiments, each of the first gate driver 321 and the first data driver 331 may be configured as three or more drivers depending on the number of gate lines GL and data lines DL.

In an embodiment, the first sub-display panel 101 includes pad electrodes PE, transmission lines, and a conductive film 200 disposed in the first display area DA1. The transmission lines include first transmission lines TL1 and second transmission lines TL2. The first transmission lines TL1 transmit corresponding gate signals received from the first gate driver 321 to corresponding gate lines GL, respectively. The second transmission lines TL2 transmit corresponding data signals received from the first data driver 331 to corresponding data lines DL, respectively. In addition, the transmission lines may further include power transmission lines that transmit a power voltage.

In an embodiment, the pad electrodes PE electrically connect the transmission lines to the first gate driver 321 or the first data driver 331. For example, each of the pad electrodes PE corresponds to each of the transmission lines, respectively. For example, the pad electrodes PE overlap the first gate driver 321 or the first data driver 331.

In an embodiment, the conductive film 200 is disposed between the pad electrodes PE and the first gate driver 321 or the first data driver 331. The conductive film 200 electrically connects the pad electrodes PE to the first gate driver 321 or the first data driver 331. Accordingly, the gate signals output from the first gate driver 321 are transmitted to the gate lines GL through the conductive film 200, the pad electrodes PE, and the first transmission lines TL1. The data signals output from the first data driver 331 are transmitted to the data lines DL through the conductive film 200, pad electrodes PE, and second transmission lines TE2.

In an embodiment, the conductive film 200 has an adhesive force, and bonds the first gate driver 321 or the first data driver 331 to the lower surface of the first sub-display panel 101. For example, the conductive film 200 includes an anisotropic conductive film (ACF).

In an embodiment, the first to ninth sub-display panels 101 to 109 have substantially the same or a similar structure as each other. In addition, the first to ninth sub-panel drivers have substantially the same or a similar structure as each other. Accordingly, hereinafter, the first sub-display panel 101 and the first sub-panel driver will be described as representative. The first sub-display panel 101 may be referred to as a display, panel, and the first sub-panel driver may be referred to as a panel driver.

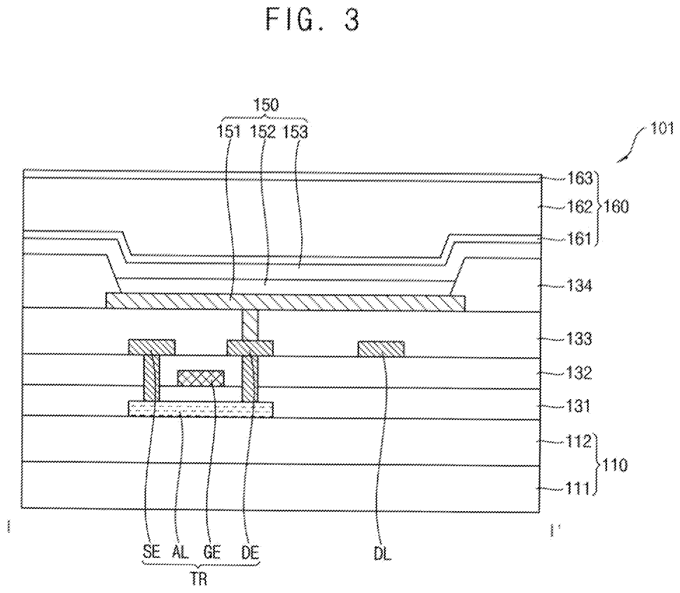

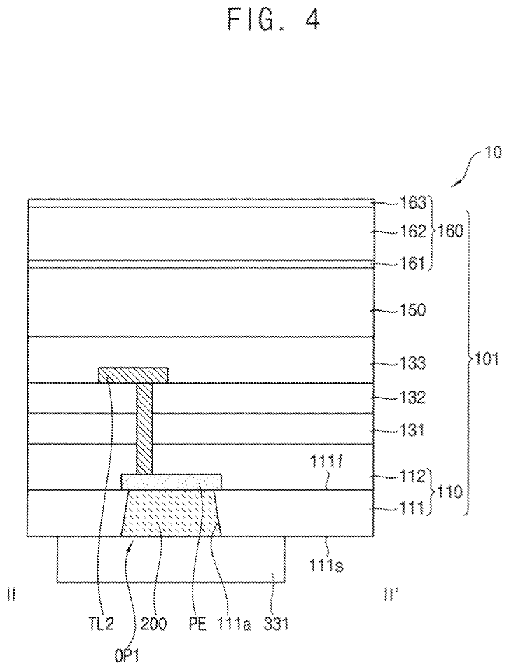

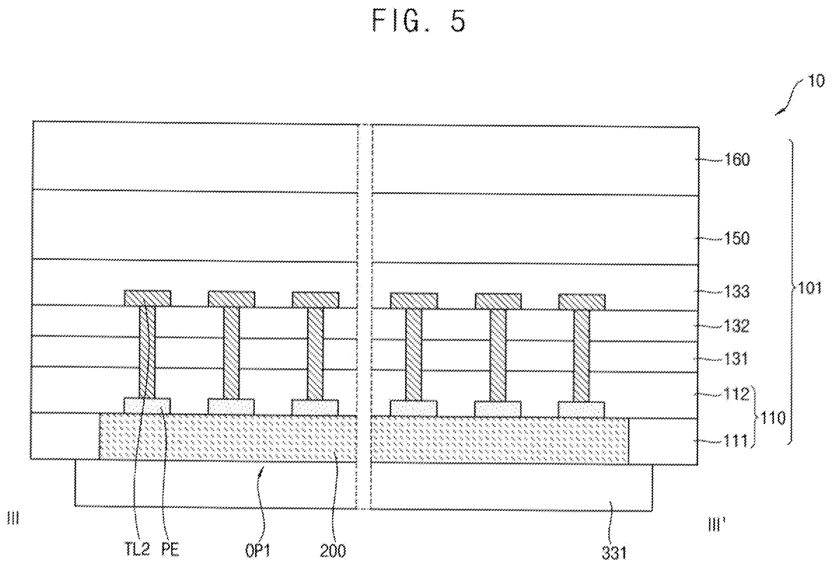

FIG. 3 is a cross-sectional view taken along line I-I′ of FIG. 2. FIG. 4 is a cross-sectional view taken along line II-II′ of FIG. 2. FIG. 5 is a cross-sectional view taken along line III-III′ of FIG. 2.

Referring to FIGS. 2 to 5, in an embodiment, the display device 10 includes the display panel 101, the conductive film 200, the gate driver 321, and the data driver 331. The display panel 101 includes a base layer 110, a pixel structure that includes a driving element TR and a light-emitting element 150, and an encapsulation layer 160.

In an embodiment, the base layer 110 may include a flexible or insulating material. For example, the base layer 110 includes a transparent resin. In detail, the base layer 110 includes polyimide (PI). For another example, the base layer 110 includes glass or quartz, etc.

In an embodiment, the base layer 110 includes a first base layer 111 and a second base layer 112 disposed on the first base layer 111. Each of the first and second base layers 111 and 112 includes a first material. That is, the first and second base layers 111 and 112 include the same material. For example, the first material includes polyimide.

In an embodiment, an active layer AL is disposed on the base layer 110. The active layer AL includes a source area, a drain area, and a channel area between the source area and the drain area. The active layer AL may be formed of amorphous silicon, polycrystalline silicon, or an oxide semiconductor, etc.

In an embodiment, a butler layer is disposed between the base layer 110 and the active layer AL. The buffer layer can prevent or reduce penetration of foreign substances or moisture from the lower portion of the base layer 110. The buffer layer includes an inorganic material such as silicon nitride or silicon oxide, etc.

In an embodiment, a first insulating layer 131 is disposed on the active layer AL and base layer 110. The first insulating layer 131 may include an inorganic insulating material such as silicon nitride or silicon oxide, etc.

In an embodiment, a gate electrode GE is disposed on the first insulating layer 131. The gate electrode GE overlaps the channel area of the active layer AL. In addition, the gate line GL is disposed in substantially the same layer as the gate electrode GE. The gate electrode GE is connected to the gate line GL and receives a gate signal front the gate driver 321 through the gate linin GL. Each of the gate electrode GE and the gate line GL includes a metal such as molybdenum (Mo) or copper (Cu), etc.

In an embodiment, a second insulating layer 132 is disposed on the gate electrode GE and the first insulating layer 131. The second insulating layer 132 includes an inorganic insulating material such as silicon nitride or silicon oxide, etc.

In an embodiment, a source electrode SE, a drain electrode DE, and a data line DL are disposed on the second insulating layer 132. The source electrode SE and the drain electrode DE are connected to the source area and the drain area of the active layer AL, respectively, by vias that penetrate the first and second insulating layers 131, 132. The source electrode SE, the drain electrode DE, and the data line DL include a metal such as aluminum (Al), titanium (Ti) or copper (Cu), etc. The active layer AL, the gate electrode GE, the source electrode SE, and the drain electrode DE form the driving element TR. The data line DL may provide the data signal to the driving element TR of the pixel structure. The source electrode SE is connected to the data line DL and receives a data signal from the data driver 331 through the data line DL.

In an embodiment, third insulating layer 133 is disposed on the source electrode SE, the drain electrode DE, and the data line DL. The third insulating layer 133 includes an organic insulating material such as polyimide or an inorganic insulating material such as silicon nitride or silicon oxide.

In an embodiment, a pixel electrode 151 is disposed on the third insulating layer 133. The pixel electrode 151 may be connected to the source electrode SE or the drain electrode DE. The pixel electrode 151 includes a metal such as magnesium (Mg), silver (Ag), gold (Au), calcium (Ca), lithium (Li), chromium (Cr) or aluminum (Al), etc, or a transparent conductive oxide such as indium tin oxide (ITO), indium zinc oxide (IZO) or zinc oxide (ZnO), etc.

In an embodiment, a fourth insulating layer 134 is disposed on the pixel electrode 151 and the third insulating layer 133. The fourth insulating layer 134 may be referred to as a pixel defining layer. The fourth insulating layer 134 covers a peripheral portion of the pixel electrode 151 and includes a pixel opening that exposes a central portion of the pixel electrode 151. The fourth insulating layer 134 includes an organic insulating material such as polyimide or polyamide, etc.

In an embodiment, an emission layer 152 is disposed on the pixel electrode 151. The emission layer 152 is disposed in the pixel opening of the fourth insulating layer 134. The emission layer 152 includes an organic emission material.

In an embodiment, a counter electrode 153 may be disposed on the emission layer 152. The counter electrode 153 is also disposed on the fourth insulating layer 134. The counter electrode 153 may include a metal such as Mg, Ag, Au, Ca, Li, Cr or Al, etc., or a transparent conductive oxide such as ITO, IZO or ZnO, etc. The pixel electrode 151, the light-emitting layer 152, and the counter electrode 153 form the light-emitting element 150 of the pixel structure.

In an embodiment, the encapsulation layer 160 is disposed on the counter electrode 153. The encapsulation layer 160 includes at least one inorganic encapsulation layer and at least one organic encapsulation layer. In an embodiment, the encapsulation layer 160 includes a first inorganic encapsulation layer 161 disposed on the counter electrode 153, an organic encapsulation layer 162 disposed on the first inorganic encapsulation layer 161, and a second inorganic encapsulation layer 163 disposed on the organic encapsulation layer 162. The inorganic encapsulation layer may include silicon oxide, silicon nitride or silicon oxynitride, etc., and the organic encapsulation layer includes an epoxy resin, an acrylic resin or a polyimide resin, etc.

In an embodiment, the display panel 101 includes the pad electrodes PE and the transmission lines. Each of the pad electrodes PE is electrically connected to the gate driver 321 or the data driver 331. Hereinafter, the pad electrodes PF electrically connected to the data driver 331 and the second transmission lines TL2 will be described as representative. The following description applies to the pad electrodes PE electrically connected to the gate driver 321 and the first transmission lines TL1.

In an embodiment, the pad electrodes PE are disposed on the first base layer 111. The pad electrodes are disposed on a first surface 111f of the first base layer 111. For example, the pad electrodes PE are disposed between the first base layer 111 and the second base layer 112. That is, the second base layer 112 is disposed on the first base layer 111 and covers the pad electrodes PE.

In an embodiment, the pad electrodes PE are spaced apart from each other in a plan view. For example, as illustrated in FIG. 2, the pad electrodes PE of the data driver 331 are spaced apart from each other in the first direction D1, and each of the pad electrodes PE extends in the second direction D2. However, the situation is reversed for pad electrodes PE of the gate driver 321. That is, the pad electrodes PE of the gate driver 321 are spaced apart from each other in the first direction D1 and extend in the second direction D2.

In an embodiment, the second transmission lines TL2 electrically connect the data lines DL to the pad electrodes PE, respectively. For example, the second transmission lines TL2 include a plurality of lines arranged in a fan-out shape. For example, the second transmission line TL2 of FIG. 4 electrically connects the pad electrode PE of FIG. 4 to the data line DL of FIG. 3. Accordingly, the pad electrode PE of FIG. 4 is electrically connected to the pixel structure of FIG. 3. For example, the transmission line TL2 is disposed in substantially the same layer as the data line DL as illustrated in FIG. 3. However, embodiments are not limited thereto. In addition, a pixel structure is omitted for convenience in FIGS. 4 and 5, but a pixel structure, such as a pixel structure that differs from the pixel structure of FIG. 3, can be disposed on the base layer 110 in FIGS. 4 and 5.

In an embodiment, the data driver 331 is disposed on a second surface 111s of the first base layer 111 that is opposite to the first surface. The pad electrodes PE overlap the data driver 331 in a plan view. The conductive film 200 is disposed between the pad electrodes PE and the data driver 331. The conductive film 200 contacts to pad electrodes PE and the data driver 331, and electrically connects the pad electrodes PE to the data driver 331.

In an embodiment, the conductive film 200 is disposed under the pad electrodes PE. A first opening OP1 that overlaps the pad electrodes PE is formed in the first base layer 111. The conductive film 200 is disposed in the first opening OP1. The data driver 331 is disposed under the conductive film 200. In an embodiment, a second material that differs from the first material is adsorbed on at least a portion of an inner side surface 111a of the first opening OP1 in the first base layer 111 forming. In an embodiment, the inner side surface 111a of the first opening OP1 is a smooth surface. This will be described in detail below.

In an embodiment, the first opening OP1 exposes a lower surface of each of the pad electrodes PE. For example, a portion of the lower surface of each of the pad electrodes PE is exposed by the first opening OP1. For another example, the entire lower surface of each of the pad electrodes PE is exposed by the first opening OP1. For example, the conductive film 200 is disposed in the first opening OP1 and contacts the pad electrodes PE and the data driver 331. For example, an upper surface of the conductive film 200 contacts the lower surface of each of the pad electrodes PE, and a lower surface of the conductive film 200 contacts an upper surface of the data driver 331. Accordingly, the conductive film 200 electrically connects the data driver 331 to the pad electrodes PE.

In an embodiment, the first opening OP1 extends in the first direction D1. That is, the first opening OP1 exposes lower surfaces of the pad electrodes PE that are spaced apart from each other in the first direction D1. In other words, the conductive film 200 contacts the pad electrodes PE. However, when the conductive film 200 is an anisotropic conductive film, the pad electrodes PE are not electrically connected to each other even if the conductive film 200 contacts the pad electrodes PE.

In some embodiments, the first opening OP1 that exposes the pad electrodes PE is formed in the first base layer 111. The conductive film 200 is disposed in the first opening OP1. The conductive film 200 electrically connects the data driver 331 to the pad electrodes PE. Accordingly, a peripheral area of each sub-display panel in the display device 10 can be minimized. Accordingly, a boundary between adjacent sub-display panels is not visually recognizable from the outside, and a display quality of the display device 10 can be improved.

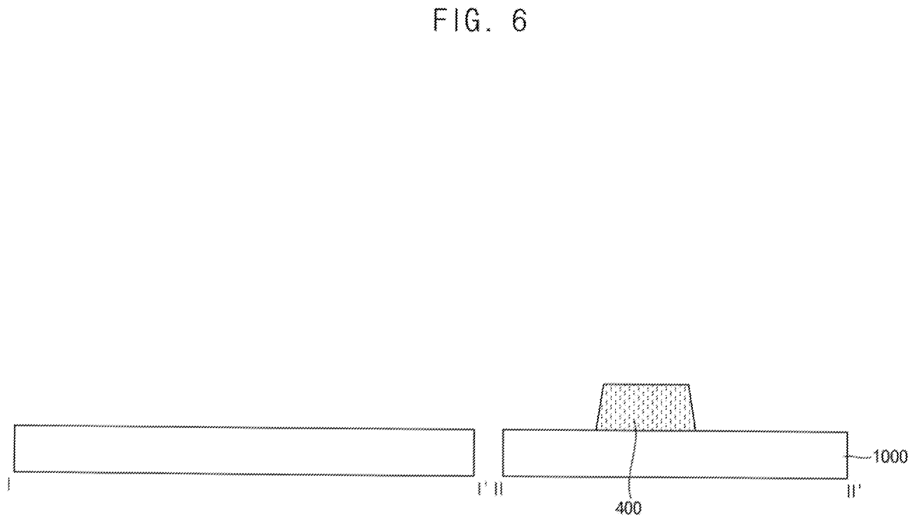

FIGS. 6 to 13 are cross-sectional views that illustrate a method of manufacturing a display device according to an embodiment.

A left cross-sectional view of each FIGS. 6 to 13 corresponds to FIG. 3, and a right cross-sectional view corresponds to FIG. 4. Therefore, repeated descriptions will be omitted.

Referring to FIG. 6, in an embodiment, a carrier substrate 1000 such as glass is prepared. Subsequently, a sacrificial layer 400 is formed on the carrier substrate 1000. The sacrificial layer 400 includes an organic material.

In an embodiment, the sacrificial layer 400 includes the second material, which differs from the first material, such as a polyimide, of the first base layer 111. As described below, after the first base layer 111 and the pad electrodes PE that contact the sacrificial layer 400 are formed, the sacrificial layer 400 is removed from the first base layer 111 and the pad electrodes PE. Accordingly, the second material may include a material that can be easily removed without damaging the first base layer 111 and the pad electrodes PE. For example, the second material includes a fluorine-based polymer such as a fluorine-based photoresist that has a low surface energy. When the sacrificial layer 400 contains a fluorine-based polymer, the sacrificial layer 400 can be removed from the first base layer 111 and the pad electrodes PE while minimizing damage to the first base layer 111 and the pad electrodes PE. In addition, the sacrificial layer 400 can be easily rem wed using a fluorine-based solvent such as hydrofluoroether (HFE). However, embodiments are not limited thereto. In other embodiments, for example, the second material includes a water-soluble material such as polyvinylalcohol.

The sacrificial layer 400 may be formed by various methods. For example, the sacrificial layer 400 can be formed by a photolithography process or an inkjet printing process. For example, an organic layer made of the second material, such as the fluorine-based photoresist, can be formed on the carrier substrate 1000. The sacrificial layer 400 can be formed by patterning the organic layer by exposure and development using a mask structure. For another example, the sacrificial layer 400 can be formed by providing an ink composition that includes the second material on the carrier substrate 1000 using an inkjet printing apparatus that includes a plurality of nozzles. When the sacrificial layer 400 is formed by a photolithography process or an inkjet printing process, a side surface of the sacrificial layer 400 has a smooth surface.

In an embodiment, the sacrificial layer 400 is formed to extend in the first direction D1. For example, the sacrificial layer 400 has a shape that corresponds to the first opening OP1. In addition, the sacrificial layer 400 is formed to have a thickness that is substantially the same as or similar to a thickness of the subsequently formed first base layer 111. For example, when the first base layer 111 is formed to have a thickness of about 20 μm, the sacrificial layer 400 is formed to have a thickness of about 19 to 21 μm.

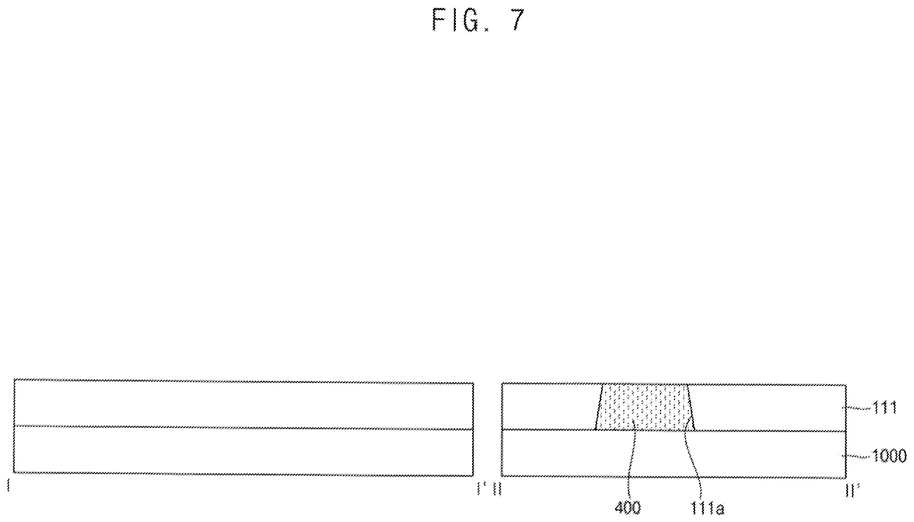

Referring to FIG. 7, in an embodiment, the first base layer 111 that surrounds the sacrificial layer 400 is formed on the carrier substrate 1000. The first base layer 111 includes the first material that differs from the second material.

In an embodiment, the first base layer 111 contacts the side surface of the sacrificial layer 400. That is, the inner side surface 111a of the first base layer 111 contacts the side surface of the sacrificial layer 400. Accordingly, the inner side surface 111a of the first base layer 111 is a smooth surface.

In an embodiment, a thickness of the first base layer 111 is substantially the same as or similar to a thickness of the sacrificial layer 400. That is, an upper surface of the sacrificial layer 400 is substantially coplanar with an upper surface of the first base layer 111. For example, each of the sacrificial layer 400 and the first base layer 111 have a substantially flat upper surface.

In an embodiment, the first base layer 111 exposes the upper surface of the sacrificial layer 400. That is, the first base layer 111 is not formed on the upper surface of the sacrificial layer 400.

In an embodiment, the first base layer 111 is formed without using a mask structure. For example, the side surface of the sacrificial layer 400 is inclined. Accordingly, when the first base layer 111 is formed by spreading the first material, such as a polyimide, on the carrier substrate 1000, the first material flows along the side surface of the sacrificial layer 400. Accordingly, the first base layer 111 is formed without using a mask structure. However, embodiments are not limited thereto. For example, in other embodiments, the first base layer 111 is formed by a photolithography process that uses a mask structure.

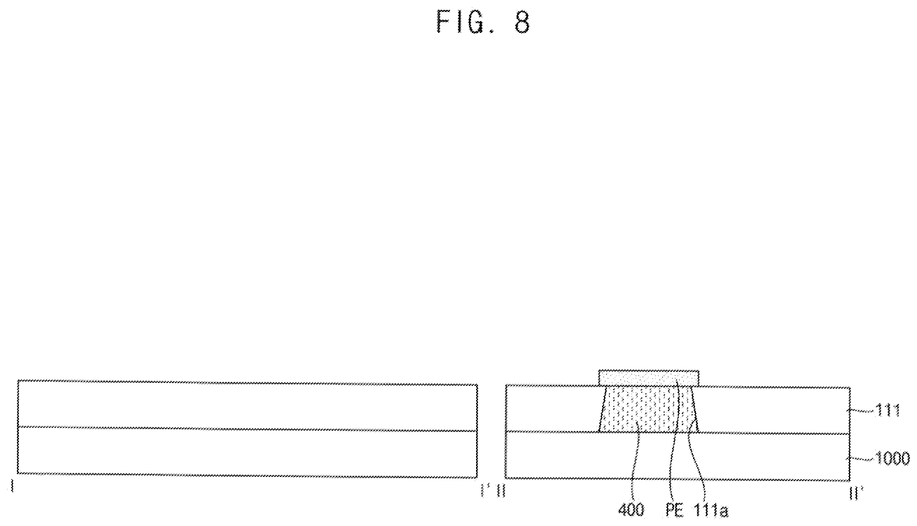

Referring to FIG. 8, in an embodiment, the pad electrodes PE that overlap the sacrificial layer 400 are formed on the first base layer 111. The pad electrodes PE contact the sacrificial layer 400. For example, lower surfaces of the pad electrodes PE contact the upper surface of the sacrificial layer 400 exposed by the first base layer 111. The pad electrodes PE are spaced apart from each other in the first direction D1, and each of the pad electrodes PE extends in the second direction D2. Accordingly, the lower surfaces of the pad electrodes PE arranged in the first direction D1 contact the upper surface of the sacrificial layer 400 that extends in the first direction D1.

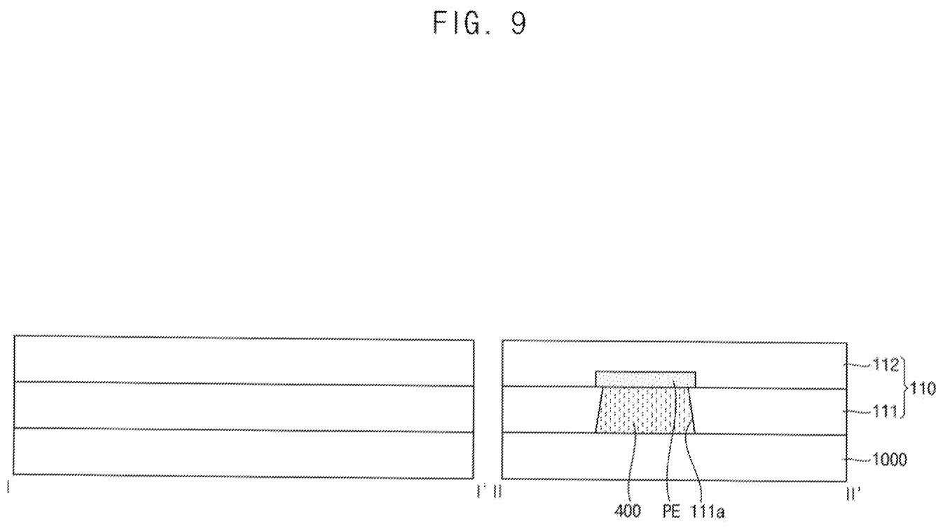

Referring to FIG. 9, in an embodiment, the second base layer 112 that covers the pad electrodes PE is formed on the first base layer 111. The second base layer 112 includes the first material, such as a polyimide. For example, the second base layer 112 can be formed by spreading the first material on the first base layer 111 and the pad electrodes PE. The second base layer 112 has a substantially flat upper surface.

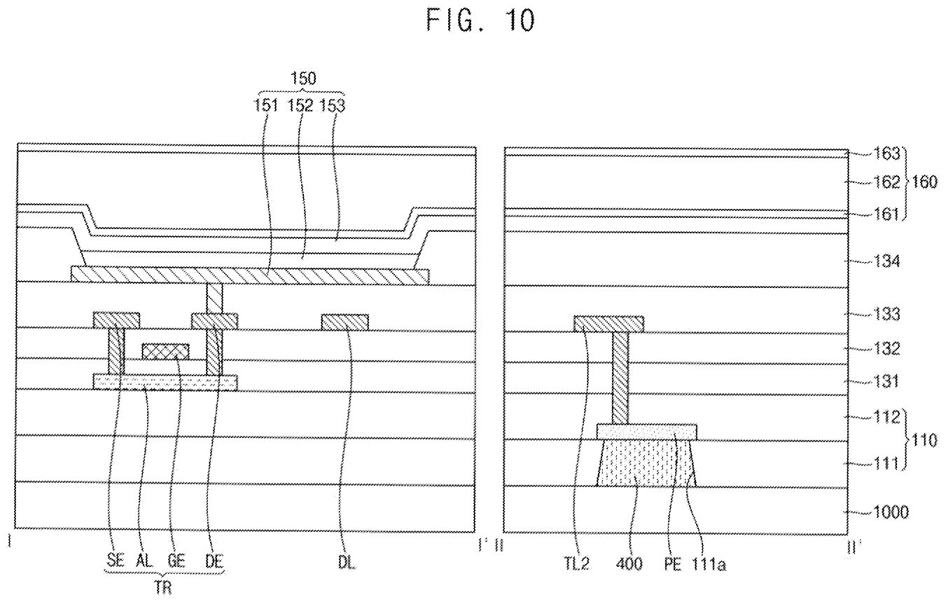

Referring to FIG. 10, in an embodiment, a pixel structure that is electrically connected to the pad electrodes PE and the encapsulation layer 160 is formed on the second base layer 112. For example, the active layer AL, the first insulating layer 131, the gate electrode GE, and the second insulating, layer 132 are sequentially formed on the second base layer 112. First and second contact holes that penetrate the first and second insulating layers 131 and 132 are formed in areas that overlap the source area and the drain area of the active layer AL, respectively. Third contact holes that penetrate the second base layer 112 and the first and second insulating layers 131 and 132 are formed in areas that overlap each of the pad electrodes PE. Subsequently, the source electrode SE, the drain electrode DE, the data line DL, and the second transmission lines TL2 are formed on the second insulating layer 132. The source electrode SE electrically contacts the source area of the active layer AL through the first contact hole. The drain electrode DE electrically contacts the drain area of the active layer AL through the second contact hole. Each of the second transmission lines TL2 electrically contacts each of the pad electrodes PE through the third contact holes. Subsequently, the third insulating layer 133, the light-emitting element 150, the fourth insulating layer 134, and the encapsulation layer 160 are sequentially formed on the second insulating layer 132.

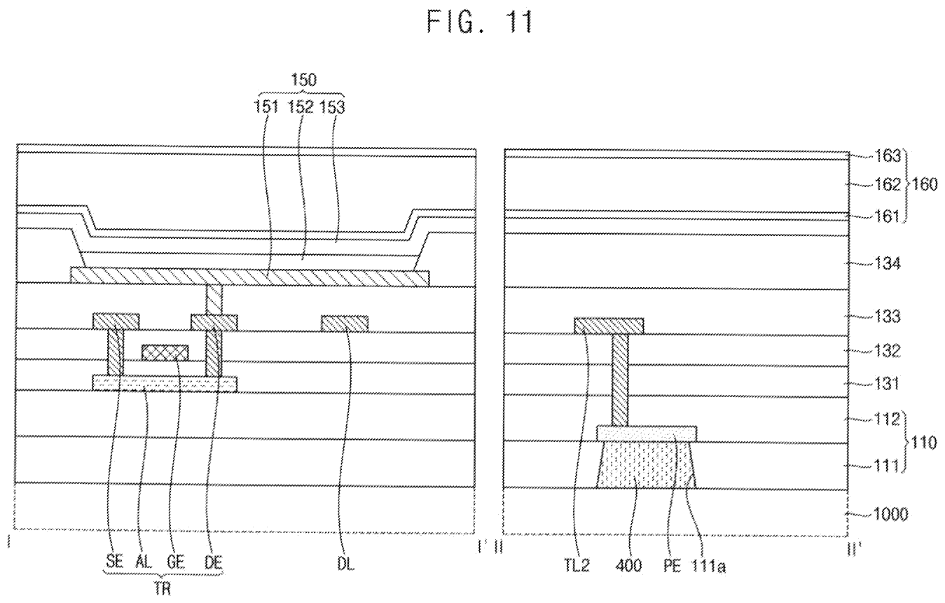

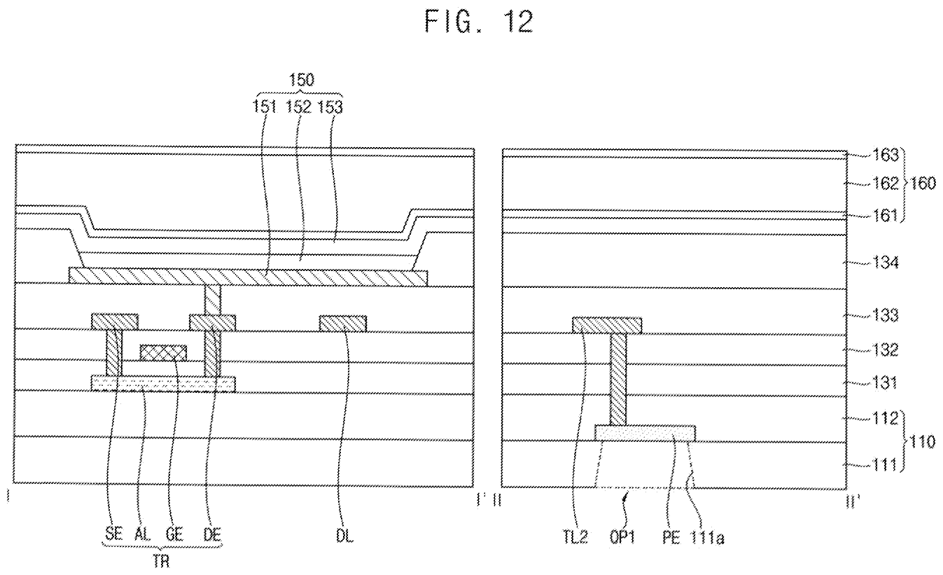

Referring to FIG. 11, in an embodiment, after the pixel structure and the encapsulation layer 160 are formed, the carrier substrate 1000 is separated from the first base layer 111 and the sacrificial layer 400, Referring to FIG. 12, after the carrier substrate 1000 is separated, the sacrificial layer 400 is removed to expose the pad electrodes PE. For example, as the sacrificial layer 400 is removed, the first opening OP1 is formed in the first base layer 111. The first opening OP1 exposes the pad electrodes PE. That is, the first opening OP1 exposes the lower surfaces of the pad electrodes PE that had previously contacted the upper surface of the sacrificial layer 400. The first opening OP1 has a shape that corresponds to the sacrificial layer 400. For example, the first opening OP1 extends in the first direction D1.

In an embodiment, the sacrificial layer 400 is removed using a solvent that corresponds to the second material. For example, when the second material includes a fluorine-based polymer, the sacrificial layer 400 is removed using a fluorine-based solvent, such as HFE, by contacting, such as dipping, the sacrificial, layer 400 to the fluorine-based solvent. The solvent does not damage the first base layer 111 and the pad electrodes PE. Accordingly, while minimizing damage to the first base layer 111 and the pad electrodes PE, the sacrificial layer 400 can be removed from first base layer 111 and the pad electrodes PE to form the first opening OP1.

In an embodiment, the second material in the sacrificial layer 400 is adsorbed on at least a portion of the inner side surface 111a of the first base layer 111. The portion of the second material adsorbed on at least the portion of the inner side surface 111a is not removed and remains on the inner side surface 111a when the sacrificial layer 400 is removed using the solvent.

For example, in an embodiment, removing the sacrificial layer 400 to expose the pad electrodes PE can be performed by a module process that includes attaching the conductive film 200 and the data driver 331 to the display panel 101.

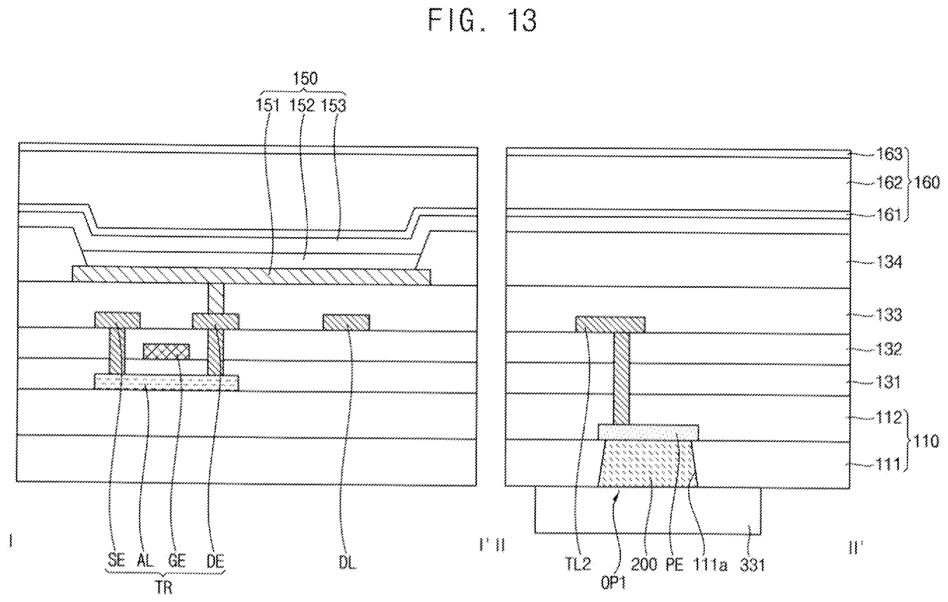

Referring to FIG. 13, in an embodiment, the conductive film 200 is disposed in the first opening OP1 of the first base layer 111. That is, the conductive film 200 is disposed wider the pad electrodes PE. For example, the conductive film 200 is attached in the first opening OP1 to contact the lower surfaces of the pad electrodes PE.

Subsequently, in an embodiment, the data driver 331 is disposed under the conductive film 200. For example, the data driver 331 is bonded to a lower surface of the display panel 101 by the conductive film 200. That is, the conductive film 200 that electrically and physically connects the data driver 331 and the pad electrodes PE is disposed in the first opening OP1 of the first base layer 111.

In some embodiments, a peripheral area of each sub-display panel in the display device 10 is minimized due to a rear bonding structure in which the data driver or the gate driver is bonded to a lower surface of each sub-display panel. Accordingly, a boundary between adjacent sub-display panels is not visually recognizable from the outside, and a display quality of the display device 10 is improved.

In a conventional method of manufacturing a display device, for a rear bonding structure, an opening is formed in a base layer by etching, such as laser etching, ion beam etching, plasma etching, etc., a portion of the base layer under the pad electrodes. In this case, particles can be generated by damaging the base layer and the pad electrodes by external energy, such as a lases, being irradiated thereon. But, it may be challenging to proceed with a cleaning process due to a risk of moisture permeation into the display device. In addition, when etching using a laser, since the laser is irradiated several times, an inner side surface of the opening or a lower surface of the pad electrodes might not be smooth. In addition, contact resistance may be increased due to oxidation of pad electrodes that include metal.

In some embodiments, the sacrificial layer 400 and the first base layer 111 that surrounds the sacrificial layer 400 are formed on the carder substrate 1000. Subsequently, the pad electrodes PE that contact the upper surface of the sacrificial layer 400 are formed on the first base layer 111. The sacrificial layer 400 is formed using a material, such as a fluorine-based polymer, that has low bonding strength with the first base layer 111 and the pad electrodes PE, and is easily removable. Subsequently, the carrier substrate 1000 and the sacrificial layer 400 are sequentially removed to form the first opening OP1 under the pad electrodes PE, thereby exposing the lower surfaces of the pad electrodes PE. Accordingly, the first opening OP1 can be formed while minimizing damage to the first base layer 111 and the pad electrodes PE. In addition, the inner side surface 111a of the first base layer 111 or the lower surfaces of the pad electrodes PE are smooth. Accordingly, it is possible to prevent or reduce an occurrence of foreign substances or oxidation of the pad electrodes PE during a manufacturing process of the display device 10. Accordingly, reliability and display quality of the display device 10 can be improved.

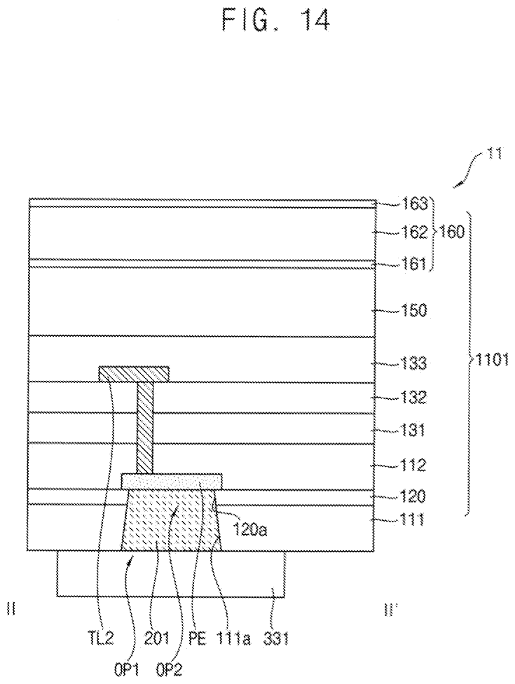

FIG. 14 is a cross-sectional view of a display device according to an embodiment.

Referring to FIG. 14, a display device 11 according to an embodiment is substantially the same as or similar to the display device 10 according to an embodiment described above with reference to FIGS. 3 to 5 except that a display panel, i.e., a first sub-display panel 1101, further includes a protective layer 120. Therefore, repeated descriptions will be omitted.

In an embodiment, the display panel 1101 may further include the protective layer 120 disposed between the first base layer 111 and the second base layer 112. In an embodiment, the protective layer 120 includes a third material that differs from the first and second materials. For example, the third material includes an inorganic material such as silicon nitride or silicon oxide, etc. For another example, the third material includes a metal oxide such as a transparent conductive oxide (TCO) or titanium oxide, etc. The protective layer 120 reduces penetration of foreign substances or moisture into the second base layer 112 or can remove an oxide film.

For example, in an embodiment, the protective layer 120 is disposed between the first base layer 111 and the pad electrodes PE. That is, the pad electrodes PE are disposed on the protective layer 120. A second opening OP2 that overlaps the pad electrodes PE and the first opening OP1 is formed in the protective layer 120. In an embodiment, the second material that differs from the third material is adsorbed on at least a portion of an inner side surface 120a of the opening OP2 of the protective layer 120. In an embodiment, the inner side surface 120a of the protective layer 120 is smooth. In an embodiment, the inner side surface 111a of the first base layer 111 is substantially coplanar with the inner side surface 120a of the protective layer 120. This will be described in detail below.

The first and second openings OP1 and OP2 expose the lower surface of each of the pad electrodes PE. For example, a conductive film 201 is disposed in the first and second openings OP1 and OP2 and contacts the pad electrodes PE and the data driver 331. Accordingly, the conductive film 201 electrically and physically connects the data driver 331 to the pad electrodes PE.

In an embodiment, the second opening OP2 extends in the first direction D1. That is, the second opening OP2 exposes lower surfaces of the pad electrodes PE spaced apart from each other in the first direction D1. Accordingly, the conductive film 201 contacts the pad electrodes PE.

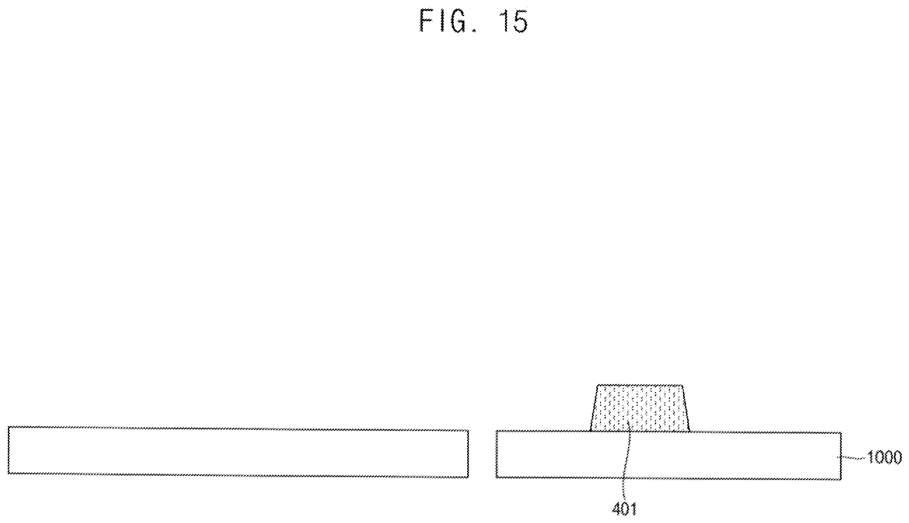

FIGS. 15 to 23 are cross-sectional views that illustrate a method of manufacturing a display device according to an embodiment.

A left cross-sectional view of each of FIGS. 15 to 23 corresponds to FIG. 3, and a right cross-sectional view corresponds to FIG. 14. Therefore, repeated descriptions will be omitted.

In a manufacturing method of the display device 11 according to an embodiment described with reference to FIGS. 15 to 23, repeated descriptions of a manufacturing method of the display device 10 according to an embodiment described with reference to FIGS. 6 to 13 will be omitted.

Referring to FIG. 15, in an embodiment, a sacrificial layer 401 is formed on the carrier substrate 1000. The sacrificial layer 401 includes the second material, such as a fluorine-based polymer. The sacrificial layer 401 is formed to have a thickness greater than a thickness of the subsequently formed first base layer 111. For example, the sacrificial layer 401 is formed to have a thickness substantially the same as or similar to a sum of the thickness of the subsequently formed first base layer 111 and a thickness of the subsequently formed protective layer 120.

For example, the sacrificial layer 401 may be formed by a photolithography process or an inkjet printing process. In either case, a side surface of the sacrificial layer 401 is smooth.

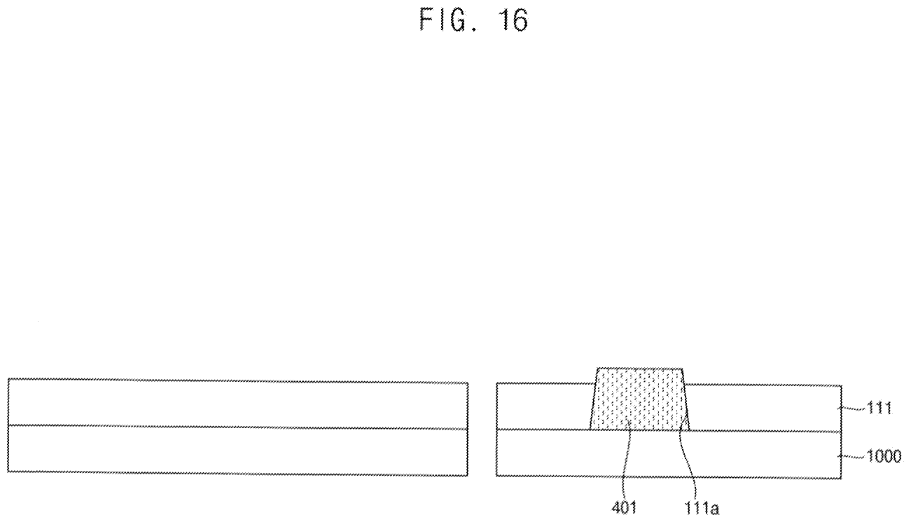

Referring to FIG. 16, in an embodiment, the first base layer 111 that surrounds the sacrificial layer 401 is formed on the carrier substrate 1000. The first base layer 111 includes the first material, such as a polyimide.

In an embodiment, a thickness of the first base layer 111 is less than a thickness of the sacrificial layer 401. For example, the first base layer 111 exposes an upper surface of the sacrificial layer 401. That is, the first base layer 111 is not formed on the upper surface of the sacrificial layer 401.

In an embodiment, the first base layer 111 can be formed without using a mask structure. For example, the side surface of the sacrificial layer 401 is inclined. Accordingly, when the first base layer 111 is formed by spreading the first material, such as a polyimide, on the carrier substrate 1000, the first material flows along the side surface of the sacrificial layer 401. Accordingly, the first base layer 111 is formed without using a mask structure. However, embodiments are not limited thereto. For example, in other embodiments, the first base layer 111 is formed by a photolithography process that uses a mask structure.

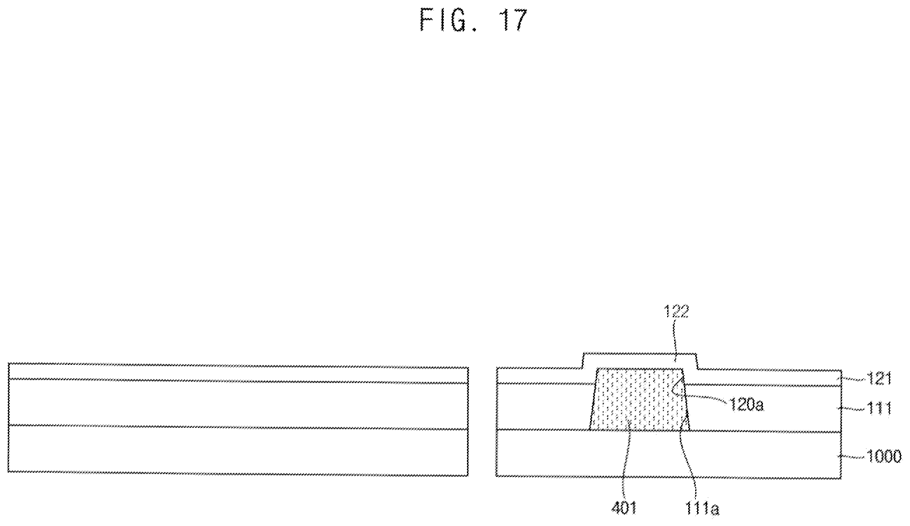

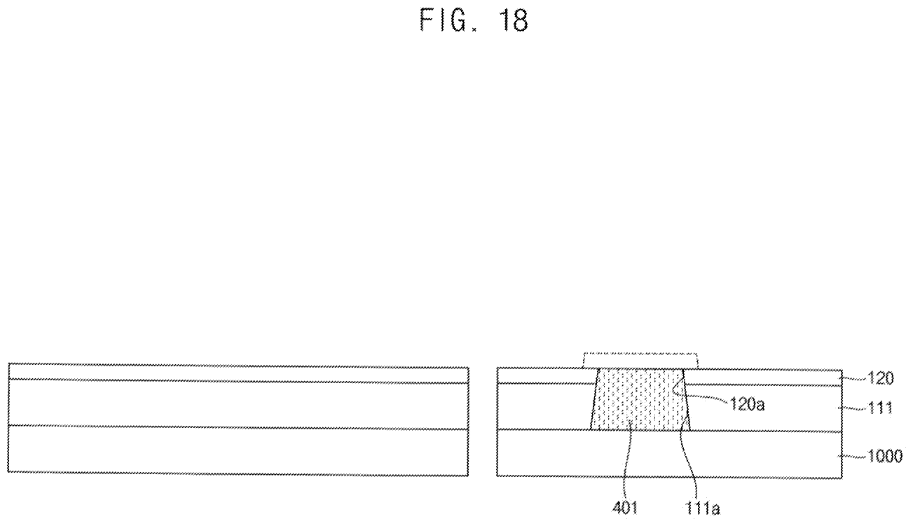

Referring to FIGS. 17 and 18, in an embodiment, the protective layer 120 that surrounds the sacrificial layer 401 is formed on the first base layer 111. The protective layer 120 includes the third material.

For example, in an embodiment, a third material layer 121 is formed on the first base layer 111 and the sacrificial layer 401 by physical vapor deposition or chemical vapor deposition using the third material. The third material layer 171 has a substantially uniform thickness along the profiles of the first base layer 111 and the sacrificial layer 401. Accordingly, the third material layer 121 includes a protrusion 122 that overlaps the sacrificial layer 401.

Subsequently, in an embodiment, the protective layer 120 is formed by removing the protrusion 122 of the third material layer 121. For example, the protrusion 122 can be removed by a photolithography process and an etching process that uses a mask structure. The protective layer 120 from which the protrusion 122 is removed exposes the upper surface of the sacrificial layer 401.

In an embodiment, a sum of the thickness of the first base layer 111 and the thickness of the protective layer 120 is substantially the same as or similar to the thickness of the sacrificial layer 401. That is, the upper surface of the sacrificial layer 401 is substantially coplanar with an upper surface of the protective layer 120.

In an embodiment, the first base layer 111 and the protective layer 120 contact the side surface of the sacrificial layer 401. That is, the inner side surface 111a of the first base layer 111 and the inner side surface 120a of the protective layer 120 contact the side surface of the sacrificial layer 401. Accordingly, the inner side surface 111a of the first base layer 111 is substantially coplanar with the inner side surface 120a of the protective layer 120. In addition, each of the inner side surface 111a of the first base layer 111 and the inner side surface 120a of the protective layer 120 is smooth.

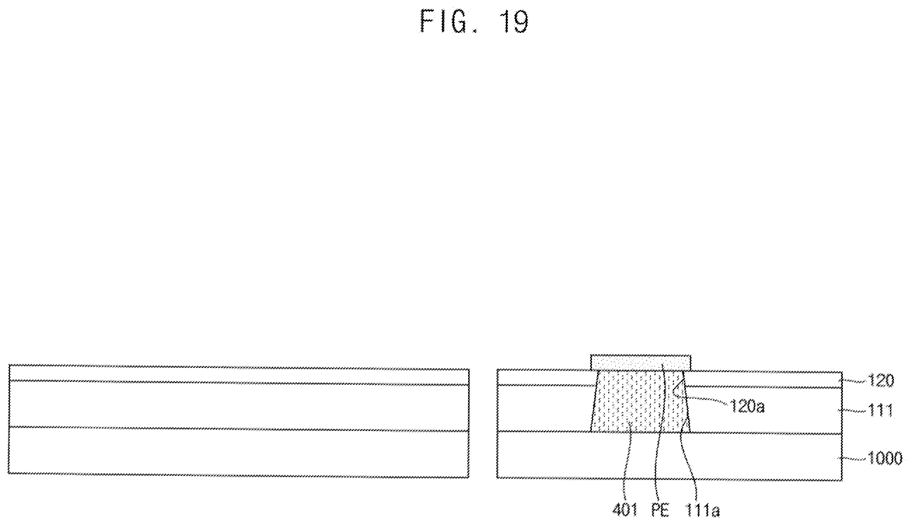

Referring to FIG. 19, in an embodiment, the pad electrodes PE that overlap the sacrificial layer 401 are farmed on the protective layer 120. The pad electrodes PE contact the sacrificial layer 401. For example, lower surfaces of the pad electrodes PE contact the upper surface of the sacrificial layer 401 exposed by the protective layer 120. The pad electrodes PE are spaced apart from each other in the first direction D1, and each of the pad electrodes PE extend in the second direction D2. Accordingly, the lower surfaces of the pad electrodes PE arranged in the first direction D1 contact the upper surface of the sacrificial layer 401 that extend in the first direction D1.

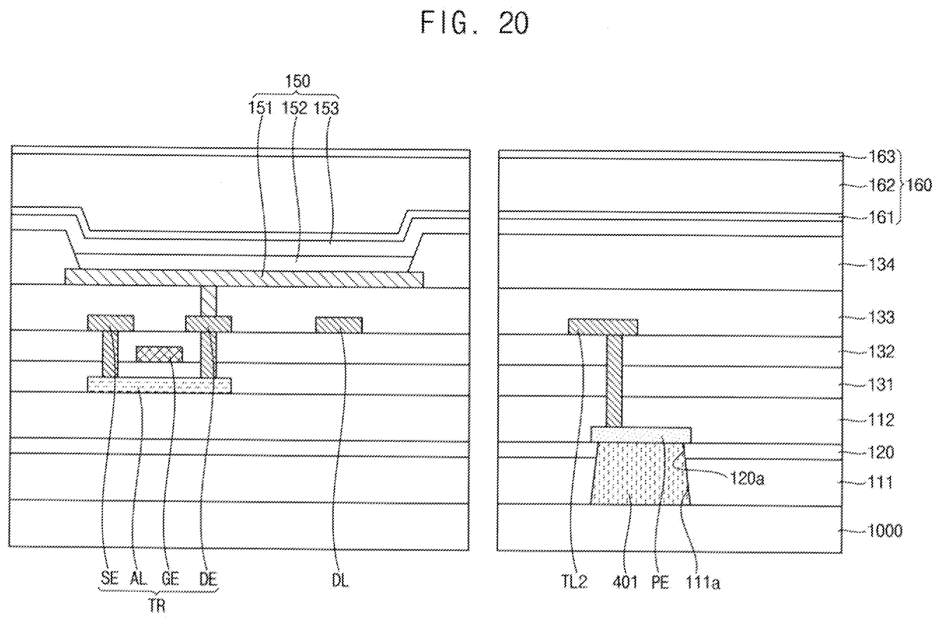

Referring to FIG. 20, the second base layer 112 that covers the pad electrodes PE is formed on the protective layer 120. The second base layer 112 includes the first material. For example, the second base layer 112 is formed by spreading the first material on the protective layer 120 and the pad electrodes PE. The second base layer 112 has a substantially flat upper surface. Subsequently, a pixel structure that is electrically connected to the pad electrodes PE and the encapsulation layer 160 is formed on the second base layer 112.

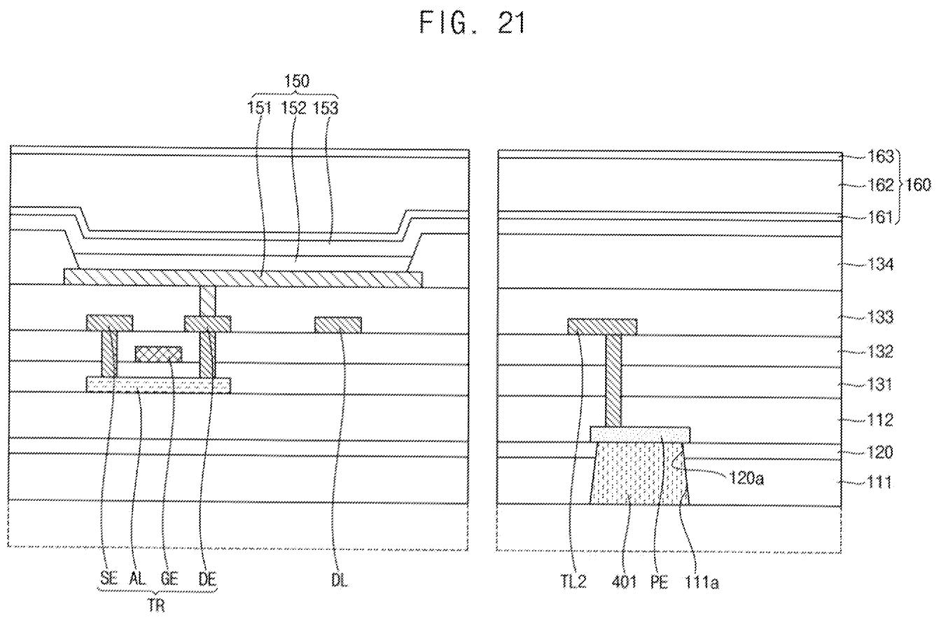

Referring to FIG. 21, in an embodiment, after the pixel structure and the encapsulation layer 160 are formed, the carrier substrate 1000 is separated from the first base layer 111 and the sacrificial layer 401.

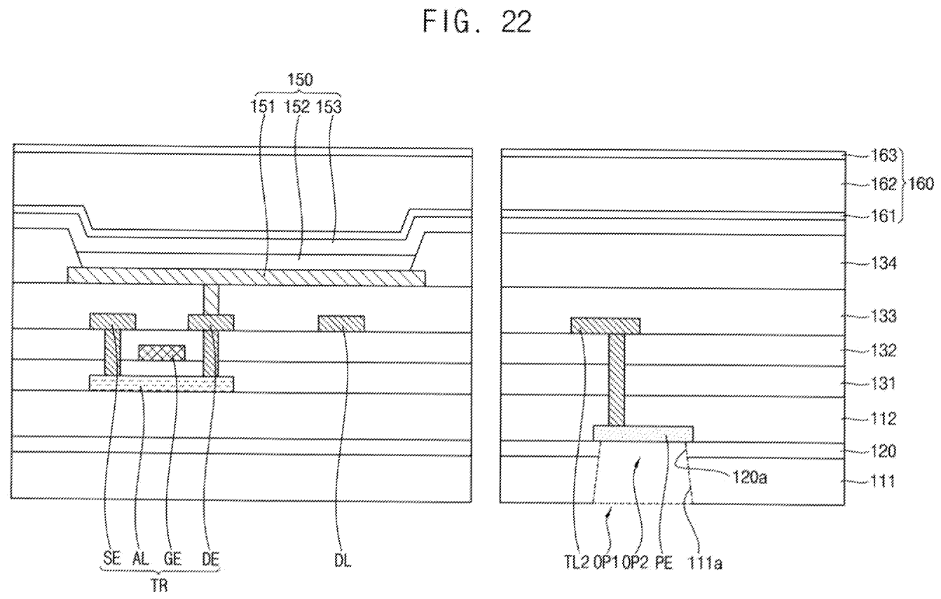

Referring to FIG. 22, in an embodiment, after the carrier substrate 1000 is separated, the sacrificial layer 401 is removed to expose the pad electrodes PE. For example, as the sacrificial layer 401 is removed, the first opening OP1 is formed in the first base layer 111 and the second opening OP2 is farmed in the second base layer 112. The first and second openings OP1 and OP2 expose the pad electrodes PE.

In an embodiment, the sacrificial layer 400 is removed using a solvent that corresponds to the second material. For example, when the second material includes a fluorine-based polymer, the sacrificial layer 401 is removed using a fluorine-based solvent, such as HFE, by contacting, such as dipping, the sacrificial layer 401 to the fluorine-based solvent. The solvent does not damage the first base layer 111, the protective layer 120, and the pad electrodes PE. Accordingly, while minimizing damage o the first base layer 111, the protective layer 120, and the pad electrodes PE, the sacrificial layer 401 can be removed from the protective layer 120, and the pad electrodes PE to form the first and second openings OP1 and OP2.

In an embodiment, the second material in the sacrificial layer 401 is adsorbed on at least a portion of the inner side surface 111a of the first base layer 111 and at least a portion of the inner side surface 120a of the protective layer 120. The portion of the second material adsorbed on at least the portion of the inner side surface 111a and at least the portion of the inner side surface 120a is not removed and remains on the inner side surface 111a and the inner side surface 120a when the sacrificial layer 401 is removed using the solvent.

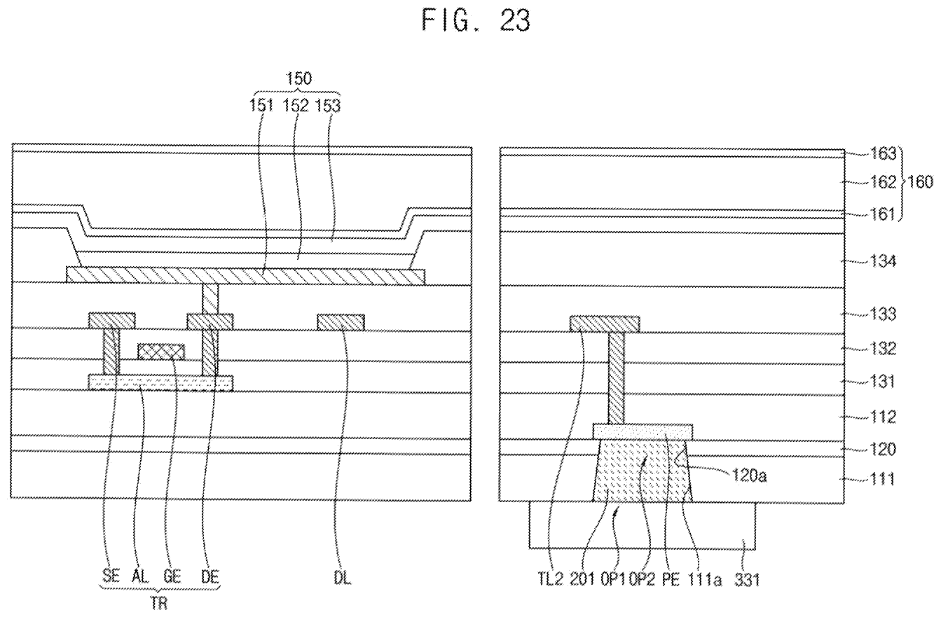

Referring to FIG. 23, in an embodiment, the conductive film 201 is disposed in the first opening OP1 of the first base layer 111 and the second opening OP2 of the second base layer 112. That is, the conductive film 201 is disposed under the pad electrodes PE. For example, the conductive film 201 is formed in the first and second openings OP1 and OP2 to contact the lower surfaces of the pad electrodes PE. Subsequently, the data driver 331 is disposed under the conductive film 201. For example, the data driver 331 is bonded to a lower surface of the display panel 1101 by the conductive film 201.

Although certain embodiments and implementations have been described herein, other embodiments and modifications will be apparent from this description. Accordingly, embodiments of the inventive concepts are not limited to such embodiments, but rather to the broader scope of the appended claims and various obvious modifications and equivalent arrangements as would be apparent to a person of ordinary skill in the art.

What is claimed is:

1. A method of manufacturing a display device, the method comprising:
forming a sacrificial layer on a carrier substrate;
forming a first base layer on the carrier substrate wherein the first base layer surrounds the sacrificial layer and includes a different material from the sacrificial layer;
forming pad electrodes on the first base layer wherein the pad electrodes contact the sacrificial layer;
forming a pixel structure on the first base layer wherein the pixel structure is electrically connected to the pad electrodes;
separating the carrier substrate from the first base layer and the sacrificial layer;
removing the sacrificial layer wherein an opening is formed in the first base layer that exposes the pad electrodes; and
attaching a conductive film in the opening of the first base layer wherein the conductive film contacts the pad electrodes.

2. The method of claim 1, wherein the first base layer contacts a side surface of the sacrificial layer and exposes an upper surface of the sacrificial layer.

3. The method of claim 1, wherein an upper surface of the sacrificial layer is substantially coplanar with an upper surface of the first base layer.

4. The method of claim 1, wherein a thickness of the first base layer is substantially the same as a thickness of the sacrificial layer.

5. The method of claim 1, wherein a thickness of the first base layer is less than a thickness of the sacrificial layer.

6. The method of claim 5, further comprising forming a protective layer on the first base layer after forming the first base layer, wherein the protective layer surrounds the sacrificial layer and includes a material that differs from that of the sacrificial layer and the first base layer.

7. The method of claim 6, wherein the protective layer contacts a side surface of the sacrificial layer and exposes an upper surface of the sacrificial layer.

8. The method of claim 6, wherein an upper surface of the sacrificial layer is substantially coplanar with an upper surface of the protective layer.

9. The method of claim 1, further comprising forming a second base layer on the first base layer after forming the pad electrodes, wherein the second base layer includes substantially a same material as that of the first base layer and covers the pad electrodes.

10. The method of claim 1, wherein the sacrificial layer includes a fluorine-based polymer.

11. The method of claim 10, wherein the sacrificial layer is formed by a photolithography process or an inkjet printing process.

12. The method of claim 10, wherein the sacrificial layer is removed using a fluorine-based solvent.

13. The method of claim 1, wherein the sacrificial layer extends in a first direction, and
wherein the pad electrodes are spaced apart from each other in the first direction, and each of the pad electrodes extends in a second direction perpendicular to the first direction.

14. A display device comprising:
a first base layer that includes a first material and a first opening;
pad electrodes disposed on the first base layer wherein the pad electrodes are exposed by the first openings;
a pixel structure disposed on the first base layer wherein the pixel structure is electrically connected to the pad electrodes; and
a conductive film disposed in the first opening wherein the conductive film contacts the pad electrodes,
wherein a second material that differs from the first material is adsorbed on at least a portion of an inner side surface of the first opening of the first base layer.

5. The display device of claim 14, wherein the second material includes a fluorine-based polymer.

16. The display device of claim 14, wherein the inner side surface of the first base layer is smooth.

17. The display device of claim 14, further comprising a protective layer disposed between the first base layer and the pad electrodes, wherein the protective layer includes a third material that differs from the first and second materials, and a second opening that overlaps the first opening, and
wherein the second material is adsorbed on at least a portion of an inner side surface of the second opening of the protective layer.

18. The display device of claim 17, wherein the inner side surface of the first base layer is substantially coplanar with the inner side surface of the protective layer.

19. The display device of claim 14, further comprising a second base layer disposed on the first base layer, wherein the second base layer includes the first material and covers the pad electrodes.

20. The display device of claim 14, wherein the first opening extends in a first direction, and
wherein the pad electrodes are spaced apart from each other in the first direction, and each of the pad electrodes extends in a second direction perpendicular to the first direction.

21. A display device comprising:
a base layer that includes a first material and a first opening;
pad electrodes disposed on a first surface of the base layer wherein the pad electrodes are exposed by the first opening;
an integrated circuit disposed on a second surface of the base layer wherein the second surface is opposite to the first surface of the base layer; and
a conductive film disposed in the first opening wherein the conductive film electrically connects the pad electrodes to the integrated circuit,
wherein the first opening extends in a first direction, and
wherein the pad electrodes are spaced apart from each other in the first direction, and each of the pad electrodes extends in a second direction perpendicular to the first direction.

22. The display device of claim 21, further comprising transmission lines on the first surface of the base layer wherein the transmission lines electrically connect the pad electrodes to a signal transmission line.

23. The display device of claim 22, further comprising a pixel structure disposed on the base layer wherein the pixel structure is electrically connected to the pad electrodes, wherein the pixel structure includes a light-emitting element and a driving element that drives the light-emitting element, wherein the driving element includes at least one thin film transistor.

24. The display device of claim 23, wherein the integrated circuit is a data driver, and the signal transmission line connects the pad electrodes to a data line that transmits data signals received from the data driver through the pad electrodes to a source electrode of the at least one thin film transistor.

25. The display device of claim 23, wherein the integrated circuit is a gate driver, and the signal transmission line connects the pad electrodes to a gate line that transmits gate signals received from the gate driver through the pad electrodes to a gate electrode of the at least one thin film transistor.

26. The display device of claim 21, wherein a second material that differs from the first material is adsorbed on at least a portion of an inner side surface of the first opening of the base layer.
